(19) United States
(12) Patent Application Publication
(10) Pub. No.: US 2009/0014160 A1
(43) Pub. Date: Jan. 15, 2009

(54) HEAT DISSIPATION MODULE

(75) Inventor: Ming-Yang Hsiao, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: ASUSTEK COMPUTER INC., Taipei (TW)

(21) Appl. No.: 12/111,974

(22) Filed: Apr. 30, 2008

(30) Foreign Application Priority Data
Jul. 13, 2007 (TW) 96125627

(51) Int. Cl. H01L 23/467

(52) U.S. Cl. 165/121

(57) ABSTRACT

A heat dissipation module including a fan and a first heat dissipation unit is provided. The fan has a frame and a blade set provided in the frame. The frame has an air inlet and an air outlet, and a flow channel communicating the air inlet and the air outlet is formed between the blade set and the frame. The first heat dissipation unit includes a first heat dissipation base, a first radiating fin assembly located inside the frame wall of the fan on the flow channel, and a first heat pipe which is connected between the first heat dissipation base and the first radiating fin assembly.

### CROSS-REFERENCE TO RELATED APPLICATION

This application claims the priority benefit of Taiwan application serial no. 96125627, filed on Jul. 13, 2008. The entirety of the above-mentioned patent application is hereby incorporated by reference herein and made a part of specification.

### BACKGROUND OF THE INVENTION

1. Field of the Invention

The invention relates to a heat dissipation module and, more particularly, to a heat dissipation module of a notebook computer.

2. Description of the Related Art

In recent years, along with the enormous progress of the computer technology, the operating speed of the computer is continuously increased, and heat generating power of electronic components in a computer housing also continuously rises. To prevent the electronic components from being overheated and temporarily or permanently losing effectiveness in the computer housing, therefore, how to dissipate the heat for the electronic components which generate the heat is an important subject.

Taking a notebook computer as an example, in the conventional technology, a fan is usually installed into the housing of the notebook computer. A radiating fin assembly connected to an electronic component is disposed outside the air outlet of the fan, so that the airflow generated by the fan can remove the heat energy which is conducted to the radiating fin assembly from the electronic component. The objective of dissipating the heat for the electronic component is achieved. However, since a notebook computer on the market is developed to be light and slim, and the inner space of the notebook computer is limited, the mode of additionally disposing a radiating fin assembly outside the air outlet of the fan is difficult to be applied to the notebook computer having limited inner space.

### BRIEF SUMMARY OF THE INVENTION

The invention provides a heat dissipation module which is suitable to be provided in a computer housing having limited inner space.

The invention provides a heat dissipation module which includes a fan and a first heat dissipation unit. The fan has a frame and a blade set provided in the frame, and the frame has an air inlet and an air outlet. A flow channel is formed between the frame and the blade set and is communicated to the air inlet and the air outlet. The blade set is suitable to impel the airflow to flow into the flow channel from the air inlet and to flow out from the air outlet.

The first heat dissipation unit includes a first heat dissipation base, a first heat pipe and a first radiating fin assembly located inside the frame wall of the fan on the flow channel. The first heat pipe has a first end and a second end. The first end is connected to the first heat dissipation base, and the second end is connected to the first radiating fin assembly.

In the heat dissipation module of the invention, the first radiating fin assembly is assembled at the inside wall of the frame and is located on the flow channel between the frame and the blade set. The airflow generated by the fan can remove the heat energy which is conducted to the first radiating fin assembly from a heat source while the airflow flows through the flow channel. Since the first radiating fin assembly is assembled at the inside wall of the frame of the fan, the heat dissipation module has a less production volume and is suitable to be provided in a computer housing which has limited inner space to dissipate the heat for the heat source in the housing.

These and other features, aspects, and advantages of the present invention will become better understood with regard to the following description, appended claims, and accompanying drawings.

### BRIEF DESCRIPTION OF THE SEVERAL VIEWS OF THE DRAWINGS

FIG. 1A is a three-dimensional schematic diagram showing the heat dissipation module of the first embodiment of the invention.

FIG. 1B is a schematic diagram showing the heat dissipation module in FIG. 1 after the upper cover of the frame is removed.

FIG. 1C is a partial exposed diagram showing the heat dissipation module in FIG. 1A.

FIG. 2A is a schematic diagram showing the heat dissipation module according to another embodiment of the invention.

FIG. 2B is a partial exposed diagram showing the heat dissipation module in FIG. 2A.

### DETAILED DESCRIPTION OF THE EMBODIMENTS

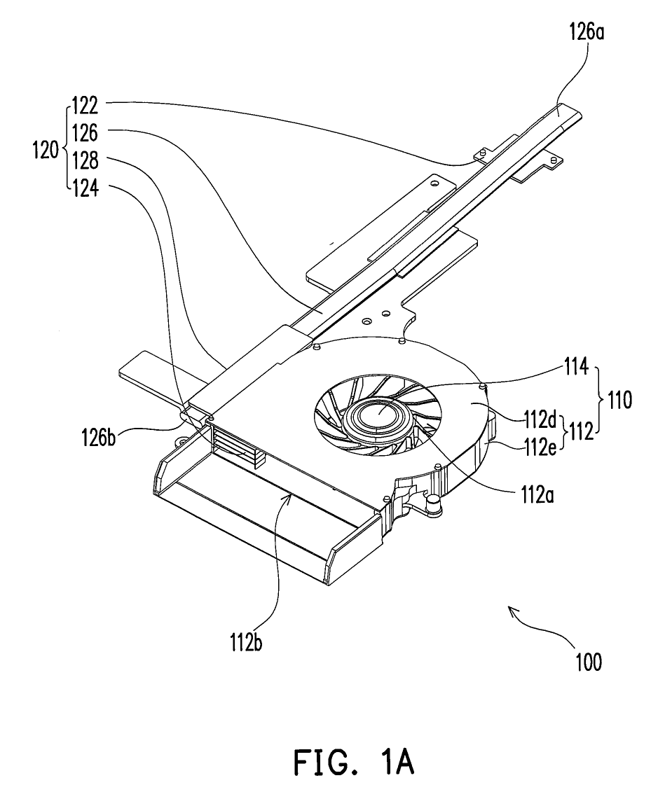

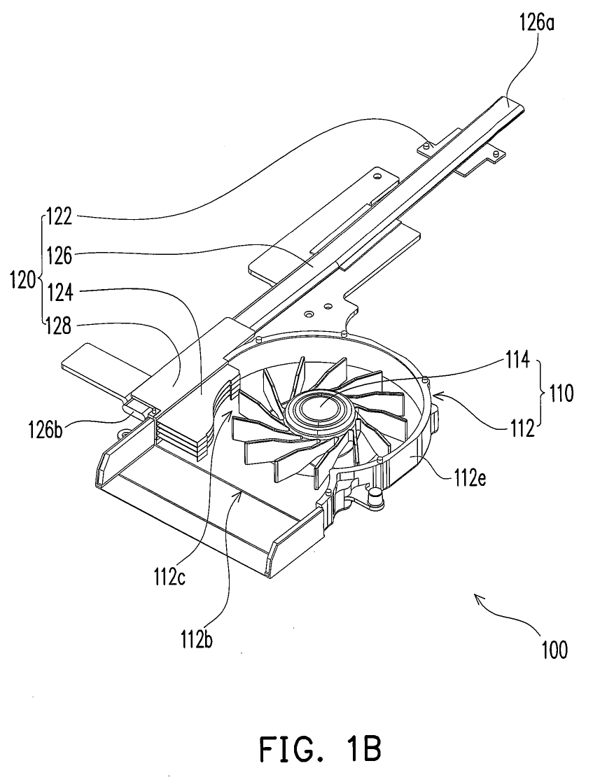

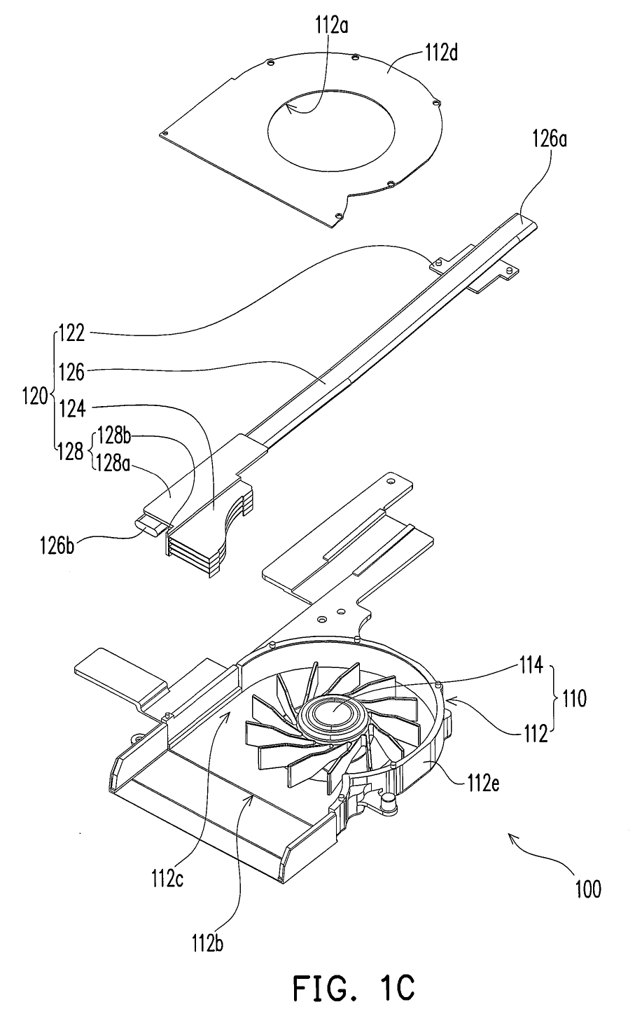

FIG. 1A is a three-dimensional schematic diagram showing the heat dissipation module of an embodiment of the invention, FIG. 1B is a schematic diagram showing the heat dissipation module in FIG. 1 after the upper cover of the frame is removed, and FIG. 1C is a partial exposed diagram showing the heat dissipation module in FIG. 1A. As shown in FIG. 1A, FIG. 1B and FIG. 1C, a heat dissipation module 100 in the embodiment is suitable to dissipate the heat for an electronic device, such as a notebook computer. Specifically, the inner of the notebook computer always has a central processing unit (CPU), a north bridge chip, a south bridge chip or other chips generating high heat power in the working state. Therefore, the heat dissipation module 100 of the embodiment is suitable to be provided on the above chips to effectively dissipate the heat for the chips, and further to enable the notebook computer to normally work. The heat dissipation module 100 of the embodiment is illustrated in details hereinbelow.

From the above, the heat dissipation module 100 mostly includes a fan 110 and a first heat dissipation unit 120. The fan 110 of the embodiment can be a blower, and has a frame 112 and a blade set 114 provided in the frame 112. The frame 112 has an air inlet 112a and an air outlet 112b. A flow channel 112c is formed between the blade set 114 and the frame 112 and is communicated to the air inlet 112a and the air outlet 112b. In detail, the frame 112 is composed of an upper cover 112d and a lower cover 112e, and the air inlet 112a is located at the upper cover 112d. The blade set 114 is provided between the upper cover 112d and the lower cover 112e, and the flow channel 112c is formed among the upper cover 112d, the lower cover 112e and the blade set 114. In the embodiment, when the fan 110 working, the blade set 114 can rotate to impel the airflow to flow into the flow channel 112c from the air inlet 112a and to flow out from the air outlet 112b.

In FIG. 1A, FIG. 1B and FIG. 1C, the first heat dissipation unit 120 of the embodiment is provided on a heat source (the heat source is a chip, such as the above chips generating the heat) to dissipate the heat for the heat source. The first heat dissipation unit 120 includes a first heat dissipation base 122 which is suitable to be connected to the heat source, a first radiating fin assembly 124 which is assembled at an inside wall of the frame 112, and a first heat pipe 126 which is connected between the first heat dissipation base 122 and the first radiating fin assembly 124. In the embodiment, a heat dissipation plate 128 is disposed on the frame 112 for connecting the first radiating fin assembly 124 and the first heat pipe 126. The first end 126a of the first heat pipe 126 is connected to the first heat dissipation base 122, and the second end 126b of the first heat pipe 126 is connected to the first radiating fin assembly 124 via the heat dissipation plate 128.

In further details, the heat dissipation plate 128 of the embodiment is composed of a first body 128a and a second body 128b which is formed by bending the first body 128a. The first body 128a is connected to the second end 126b of the first heat pipe 126, the second body 128b is formed by bending the first body 128a to the inside wall of the frame 112, and the first radiating fin assembly 124 is provided at the second body 128b of the heat dissipation plate 128. In this way, the heat energy generated by the heat source can be effectively conducted to the first radiating fin assembly 124 via the first heat pipe 126 and the heat dissipation plate 128.

In the embodiment, the first radiating fin assembly 124 assembled at the inside wall of the frame 112 is located on the flow channel 112c (that is, the first radiating fin assembly 124 is assembled inside the air outlet 112b) between the frame 112 and the blade set 114, and the first radiating fin assembly 124 is connected with the partial section of the air outlet 112b. Therefore, while the airflow generated by the blade set 114 flows through the flow channel 112c, the airflow removes the heat energy which is conducted to the first radiating fin assembly 124 from the heat source, and further effectively dissipates the heat for the heat source. Since the first radiating fin assembly 124 is assembled at the inside wall of the frame 112, the heat dissipation module 100 has a less production volume and is suitable to be provided in the computer housing having limited inner space. The first radiating fin assembly 124 assembled at the inside wall of the frame 112 has a streamlined shape, and therefore, the first radiating fin assembly 124 can effectively regularize the airflow flowing through the flow channel 112c to improve the work efficiency of the fan 110.

The frame 112 of the embodiment is made of a metal having good heat conductivity. The partial first heat pipe 126 between the first end 126a and the second end 126b can be connected to the frame 112 or a metal plate extending from the frame 112. Since the frame 112 has a large area for exchanging heat with the environment, the heat energy generated by the heat source can be conducted to the frame 112 via the first heat pipe 126 and is convected to the ambient environment via the frame 112.

In the above embodiment, the heat dissipation module 100 only utilizes one first heat dissipation unit 120 to dissipate the heat for the heat source. However, in other preferred embodiments, the invention can add another heat dissipation unit in the heat dissipation module to dissipate the heat for other heat source. The embodiment in which another heat dissipation unit is added to the heat dissipation module is illustrated in detail hereinbelow.

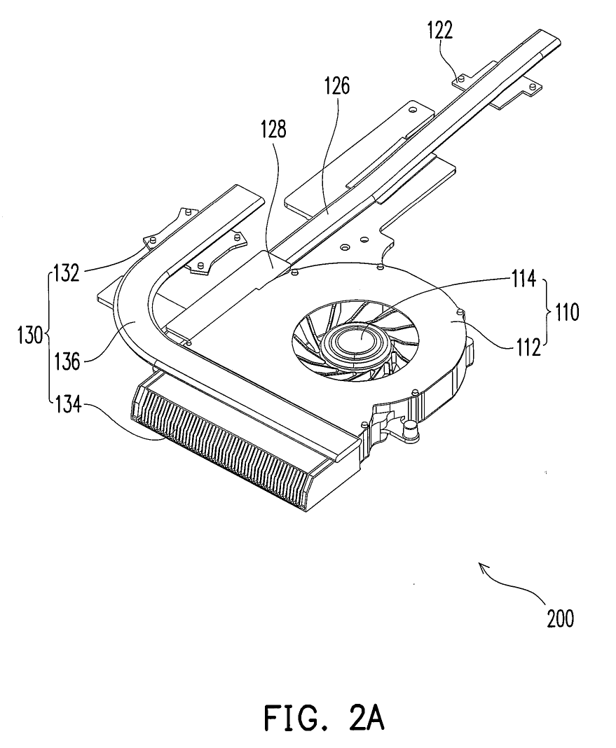

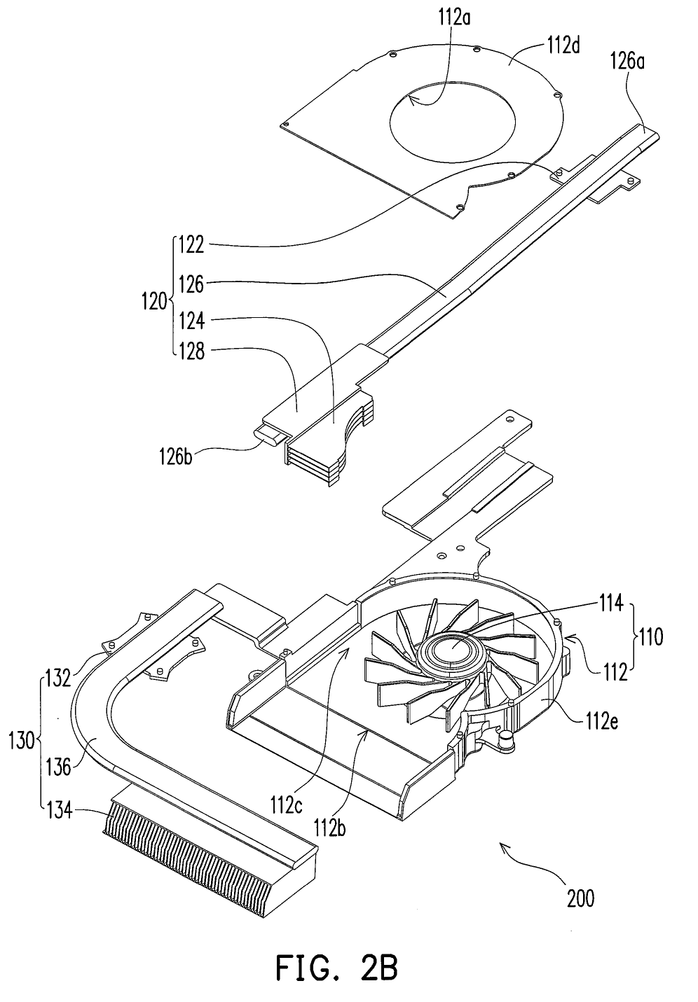

FIG. 2A is a schematic diagram showing the heat dissipation module according to another embodiment of the invention, and FIG. 2B is a partial exposed diagram showing the heat dissipation module in FIG. 2A. As shown in FIG. 2A and FIG. 2B, a heat dissipation module 200 of the embodiment is similar to the heat dissipation module 100 of the above embodiment. The main difference between them is that a second heat dissipation unit 130 is further provided at the heat dissipation module 200 of the embodiment. The composing structure of the second heat dissipation unit 130 and the position where the second heat dissipation unit 130 is provided in the embodiment are illustrated hereinbelow.

In the embodiment, the second heat dissipation unit 130 mostly includes a second heat dissipation base 132, a second radiating fin assembly 134 and a second heat pipe 136. The second heat dissipation base 132 is suitable to be connected to another heat source, and the second radiating fin assembly 134 is disposed outside the air outlet 112b. In addition, the second heat pipe 136 is connected between the second heat dissipation base 132 and the second radiating fin assembly 134 to conduct the heat energy generated by another heat source to the second radiating fin assembly 134. The first radiating fin assembly 124 assembled at the inside wall of the frame 112 can effectively regularize the airflow flowing through the flow channel 112c. As a result, after the airflow generated by the blade set 114 passing through the flow channel 112c and flowing out from the air outlet 112b, the airflow can effectively pass through the whole second radiating fin assembly 134 and further effectively remove the heat energy which is conducted to the second radiating fin assembly 134 from another heat source.

The heat dissipation area of the second radiating fin assembly 134 of the embodiment is larger than the heat dissipation area of the first radiating fin assembly 124, so a user can make the second heat dissipation base 132 of the second heat dissipation unit 130 provide on the heat source with higher heat generating power. This enables the whole heat dissipation module 200 effectively dissipates the heat for a plurality of heat sources in the computer housing. The whole size of the second radiating fin assembly 134 of the embodiment can be designed according to the inner installation space of the computer housing. This makes the heat dissipation module 200 with the second radiating fin assembly 134 be successfully provided in the computer housing, similarly.

To sum up, the heat dissipation module of the invention mostly utilizes a fan and a first heat dissipation unit to dissipate the heat for a heat source in a computer housing. The first radiating fin assembly of the first heat dissipation unit is located on the flow channel in the fan and is assembled at the inside wall of the frame of the fan. Therefore, while the airflow generated by the blade set flows through the flow channel, it removes the heat energy which is conducted to the first radiating fin assembly from the heat source.

Compared with the conventional technology, since the first radiating fin assembly of the first heat dissipation unit is assembled at the inside wall of the frame of the fan, the heat dissipation module of the invention has less production volume and is suitable to be provided in the computer housing having limited space further to effectively dissipate the heat for the heat source in the housing.

In the invention, a second heat dissipation unit can be selectively added into the heat dissipation module to dissipate the heat for another heat source. The whole size of the second radiating fin assembly of the second heat dissipation unit can be designed according to the inner installation space of the computer housing, so that the heat dissipation module having the second heat dissipation unit is also suitable to be provided in the computer housing with limited space.

On the other hand, in the invention, the first radiating fin assembly has a streamlined shape, the first radiating fin assembly can effectively regularize the airflow flowing through the flow channel and further enable the airflow generated by the blade set to effectively pass through the whole second radiating fin assembly. As a result, the heat energy conducted to the second radiating fin assembly from another heat source is effectively removed, and the heat dissipation efficiency of the heat dissipation module is increased.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A heat dissipation module comprising:
a fan having a frame and a blade set provided in the frame, wherein the frame has an air inlet and an air outlet, a flow channel is formed between the frame and the blade set and is communicated with the air inlet and the air outlet, and the blade set is suitable to impel the airflow to flow into the flow channel from the air inlet and to flow out from the air outlet; and
a first heat dissipation unit having a first heat dissipation base, a first radiating fin assembly located inside the frame wall of the fan on the flow channel, and a first heat pipe including a first end and a second end, wherein the first end is connected to the first heat dissipation base, and the second end is connected to the first radiating fin assembly.

2. The heat dissipation module according to claim 1, wherein the first heat dissipation unit further comprises a heat dissipation plate having a first body and a second body which extends from the first body, the first body is connected to the second end of the first heat pipe, the second body extends to the inside wall of the frame, and the first radiating fin assembly is provided at the second body.

3. The heat dissipation module according to claim 1, wherein the frame is made of a metal.

4. The heat dissipation module according to claim 1, wherein a partial first heat pipe between the first end and the second end is connected to the frame.

5. The heat dissipation module according to claim 1, wherein the first radiating fin assembly is connected with a partial section of the air outlet.

6. The heat dissipation module according to claim 1 further comprising a second heat dissipation unit which is provided outside the air outlet.

7. The heat dissipation module according to claim 6, wherein the second heat dissipation unit comprises a second heat dissipation base, a second heat pipe and a second radiating fin assembly.

8. The heat dissipation module according to claim 7, wherein the second radiating fin assembly is provided outside the air outlet, and the second heat pipe is connected between the second heat dissipation base and the second radiating fin assembly.

9. The heat dissipation module according to claim 1, wherein the fan is a blower.
